(19) United States
(12) Patent Application Publication
(10) Pub. No.: US 2025/0087972 A1
(43) Pub. Date: Mar. 13, 2025

(54) LONG-WAVELENGTH POLARIZED OPTICAL EMITTER

(71) Applicant: Lumentum Operations LLC, San Jose, CA (US)

(72) Inventors: Matthew Glenn PETERS, Menlo Park, CA (US); Jun YANG, Cupertino, CA (US)

(21) Appl. No.: 18/727,587

(22) PCT Filed: Jan. 23, 2023
(86) PCT No.: PCT/US2023/061094

§ 371 Date: Jul. 9, 2024

Related U.S. Application Data
(60) Provisional application No. 63/267,088, filed on Jan. 24, 2022.

(51) Int. Cl. H01S 5/343; H01S 5/042; H01S 5/183

(52) U.S. Cl. CPC H01S 5/34306; H01S 5/04254; H01S 5/18311; H01S 5/18355; H01S 5/18394; H01S 2301/176

(57) ABSTRACT

In some implementations, an optical emitter includes a substrate with a surface that is off-cut relative to an orientation of a crystallographic plane of the substrate; a first set of layers disposed on the substrate and forming an active region of a light emitting junction, wherein the first set of layers includes a gallium-arsenic-nitrogen (GaAsN) material layer, wherein the GaAsN material layer forms a quantum well barrier, wherein the first set of layers further includes an indium-gallium-arsenic-nitrogen-antimony (InGaAsNSb) layer, wherein the InGaAsNSb layer is a strained, dilute nitride InGaAsNSb layer forming a quantum well; and a second set of layers forming a first distributed Bragg reflector (DBR) and a second DBR, wherein the active region is disposed between the first DBR and the second DBR.

### CROSS-REFERENCE TO RELATED APPLICATION

This Patent Application claims priority to U.S. Provisional Patent Application No. 63/267,088, filed on Jan. 24, 2022, and entitled “LONG-WAVELENGTH POLARIZED VERTICAL CAVITY SURFACE EMITTING LASERS (VCSELS).” The disclosure of the prior Application is considered part of and is incorporated by reference into this Patent Application.

### TECHNICAL FIELD

The present disclosure relates generally to optical emitters and to a long-wavelength polarized optical emitter.

### BACKGROUND

Optical emitters, such as vertical cavity surface emitting lasers (VCSELs) and edge emitting lasers (EELs), can be used for emitting polarized beams in telecommunications applications or three-dimensional (3D) sensing applications. A polarization extinction ratio (PER) is a ratio of optical powers in perpendicular polarizations of a beam. For example, the PER can represent a comparison of an optical power in a desired polarization state relative to an optical power in an undesired polarization state. The PER of an optical emitter may be dependent on one or more factors, such as a current being applied to the optical emitter or an operating temperature of the optical emitter.

### SUMMARY

In some implementations, an optical emitter includes a substrate with a surface that is off-cut relative to an orientation of a crystallographic plane of the substrate: a first set of layers disposed on the substrate and forming an active region of a light emitting junction, wherein the first set of layers includes a gallium-arsenic-nitrogen (GaAsN) material layer, wherein the GaAsN material layer forms a quantum well barrier, wherein the first set of layers further includes an indium-gallium-arsenic-nitrogen-antimony (InGaAsNSb) layer, wherein the InGaAsNSb layer is a strained, dilute nitride InGaAsNSb layer forming a quantum well: and a second set of layers forming a first distributed Bragg reflector (DBR) and a second DBR, wherein the active region is disposed between the first DBR and the second DBR.

In some implementations, an optical system includes an array of optical emitters, each optical emitter, of the array of optical emitters, including: a gallium-arsenide (GaAs) substrate with a surface that is off-cut relative to an orientation of a crystallographic plane of the GaAs substrate, a first DBR disposed on the GaAs substrate, a second DBR, and an active region disposed between the first DBR and the second DBR, the active region including a set of layers, wherein the set of layers includes a GaAsN material layer and an InGaAsNSb layer.

In some implementations, an optical emitter includes a first set of layers forming an active region of a light emitting junction, wherein the first set of layers includes a GaAsN material layer, wherein the GaAsN material layer forms a quantum well barrier, wherein the first set of layers further includes an InGaAsNSb layer, wherein the InGaAsNSb layer is a strained, dilute nitride InGaAsNSb layer forming a quantum well, and a second set of layers forming a first DBR and a second DBR, the active region being disposed between the first DBR and the second DBR, wherein the second set of layers includes a material with greater than a threshold refractive index: and an oxidation aperture.

### BRIEF DESCRIPTION OF THE DRAWINGS

FIGS. 1A and 1B are diagrams depicting a top view of an example emitter and a cross-sectional view of example emitter along the line X-X, respectively.

FIG. 2 is a diagram of an example optical emitter associated with long-wavelength polarized emission.

FIG. 3 is a diagram of an example associated with an oxidation aperture for long-wavelength polarized emission.

FIG. 4 is a diagram of an example associated with an off-cut substrate for long-wavelength polarized emission.

### DETAILED DESCRIPTION

The following detailed description of example implementations refers to the accompanying drawings. The same reference numbers in different drawings may identify the same or similar elements.

An optical emitter array may include a set of optical emitters, such as a set of vertical cavity surface emitting lasers (VCSELs) or a set of edge-emitting lasers (EELs), among other examples. An optical emitter, of the optical emitter array, may emit a beam for use in telecommunications applications, three-dimensional (3D) sensing applications, measurement applications, or gesture recognition applications, among other examples. EELs may include strained quantum-well (QW) active regions in a direction of lasing, resulting in an emission of an inherently polarized beam. However, EELs may not achieve a stable spectral output across a wide range of wavelengths or temperatures. In contrast, a VCSEL may use a symmetric (e.g., round) aperture for high efficiency and may emit a beam, perpendicular to an active region, with little polarization selectivity. VCSELs can achieve stable spectral output across a wide range of wavelengths and/or temperatures and can be closely integrated with other optics for use in increasingly miniaturized optical systems and increasingly dense optical emitter arrays. However, VCSELs may not achieve a high polarization extinction ratio (PER) across a range of currents and temperatures. This may result in inefficient lasing and/or poor performance in applications in which a high PER is advantageous.

Some implementations described herein provide a VCSEL with a high PER for polarized light emission across a configured range of currents and/or a configured range of temperatures, as described below. For example, a VCSEL may include an indium-gallium-arsenic-nitrogen (InGaAsN) material or an indium-gallium-arsenic-nitrogen-antimony (InGaAsNSb) material for a quantum well, a gallium-arsenic-nitrogen (GaAsN) material for a quantum well barrier, an off-cut gallium-arsenide (GaAs) substrate, or an oxidation aperture of less than a threshold diameter, among other examples. In this way, an optical emitter array, which includes the VCSEL, can achieve a high PER for long-wavelength applications, thereby enabling efficient lasing and a high level of performance.

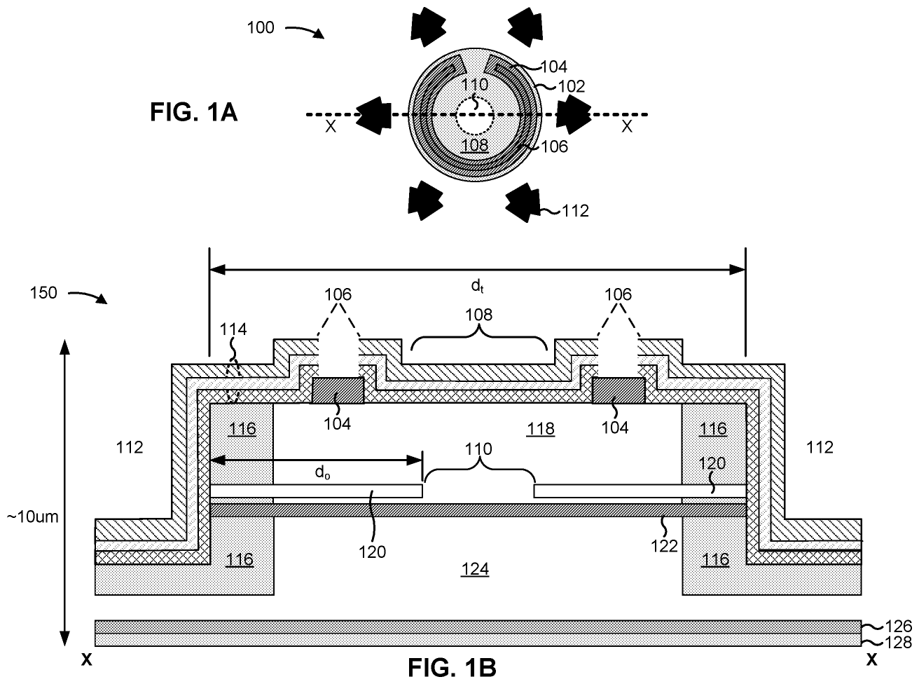

FIGS. 1A and 1B are diagrams depicting a top view of an example emitter 100, and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown in FIG. 1A, emitter 100 includes an ohmic metal layer 104 (e.g., a P-Ohmic metal layer or an N-Ohmic metal layer) that is constructed in a partial-ring shape (e.g., with an inner radius and an outer radius). The medium gray area shows an area of ohmic metal layer 104 covered by a protective layer (e.g., a dielectric layer or a passivation layer) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium grey area shows an area of ohmic metal layer 104 that is covered by a protective layer. The protective layer may cover all of the emitter other than the vias. As shown, via 106 is formed in a partial-ring shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full-ring shape or a split-ring shape.

As further shown, emitter 100 includes an optical aperture 108 in a portion of emitter 100 within the inner radius of the partial-ring shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances. The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dₜ. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g., a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as an gold-germanium-nickel (AuGeNi) layer, a palladium-germanium-gold (PdGeAu) layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an aluminum-oxide (Al₂O₃) layer formed as a result of oxidation of an aluminum-arsenide (AlAs) or an aluminum-gallium-arsenide (AlGaAs) layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically-defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a silicon dioxide (SiO₂) layer, a silicon nitride (Si₃N₄) layer, an aluminum oxide (Al₂O₃) layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or as a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

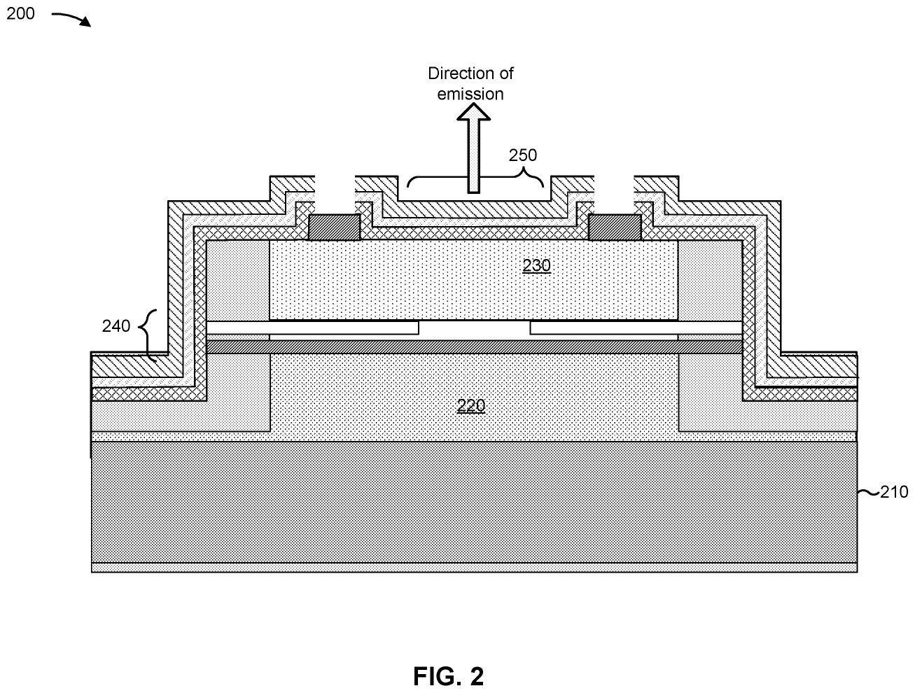

FIG. 2 is a diagram of an example optical emitter 200 associated with long-wavelength polarized emission. As shown in FIG. 2, optical emitter 200 includes a substrate 210, a first reflector 220, a second reflector 230, an active region 240, and an oxidation aperture 250.

The substrate 210 may include a material with a crystalline structure onto which the first reflector 220 is disposed and/or formed. For example, the substrate 210 may include a gallium-arsenide (GaAs) material. In some implementations, the substrate 210 may be associated with a surface that is cut relative to a crystallographic plane of the crystalline structure of the substrate 210. For example, the substrate 210 may have a top surface (onto which the first reflector 220 is disposed) that has a plane cut normal to the crystallographic plane of the substrate 210. Additionally, or alternatively, the substrate 210 may have a top surface that has a plane off-cut relative to the crystallographic plane of the substrate 210. In this case, the off-cut of the top surface relative to the crystallographic plane may be approximately 2 degrees, as described in more detail below. Additionally, or alternatively, the off-cut of the top surface relative to the crystallographic plane may be greater than or equal to 2 degrees. In this way, by using a substrate 210 with the top surface off-cut relative to the crystallographic plane, the optical emitter 200 may achieve a higher PER value across a wider range of currents and temperatures than is achieved by other optical emitters that use a normal-cut substrate.

The first reflector 220 and the second reflector 230 may include DBRs that sandwich the active region 240. For example, each of the first reflector 220 and the second reflector 230 may include a set of alternating layers of material with different refractive indices. In other words, first reflector 220 may include a set of alternating layers of a first material with a first refractive index (e.g., a relatively low refractive index) and a second material with a second refractive index (e.g., a relatively high refractive index). Similarly, the second reflector 230 may include another set of alternating layers of a first material (e.g., the same first material or a different first material) and a second material (e.g., the same second material or a different second material). A reflectivity of the reflectors 220 and 230 may be based at least in part on a refractive index, a quantity of layers, and/or a thickness of materials included therein. For example, the first reflector 220 and the second reflector 230 may include one or more GaAs material layers (e.g., alternating with another material layer). In some implementations, one or more material layers, such as one or more GaAs material layers, may be cavity cladding layers. Although some aspects are described herein in terms of DBR-based reflectors, another type of reflector may be used. Additionally, or alternatively, although some aspects are described herein in terms of a single active region 240 sandwiched between a single pair of reflectors, an optical emitter may include multiple active regions sandwiched between one or more pairs of reflectors.

The active region 240 may include a set of layers of material forming a set of quantum wells (QWs) and/or quantum well barriers (QW barriers). For example, the active region 240 may include one or more layers of GaAs-based dilute nitride, such as an InGaAsN material or an InGaAsNSb material, that may enable use for long-wavelength applications, such as applications at wavelengths of 1200 nanometers (nm) or higher. In some implementations, the active region 240 may have multiple materials. For example, the active region 240 may include a GaAsN material layer forming a quantum well barrier and an InGaAsNSb layer forming a quantum well. In this case, the InGaAsNSb layer may be a strained, dilute-nitride InGaAsNSb layer forming the quantum well. A strained quantum well is a type of quantum well formed by one or more layers of material under compressive strain to produce a beam with a higher degree of concentration, resulting in more efficient operation. Additionally, or alternatively, the active region 240 may include a GaAsN material layer forming a quantum well barrier and an InGaAsN layer forming a quantum well. Additionally, or alternatively, the active region 240 may include a plurality of layers forming a quantum well barrier and a plurality of layers forming a quantum well. Additionally, or alternatively, the active region 240 may include a plurality of quantum wells (e.g., configured for the same or different wavelengths of emission) and/or a plurality of quantum well barriers.

In some implementations, one or more layers of the active region 240 (or another one or more layers described herein, such as layers of a reflector 220 or 230) may be formed using a particular formation process. For example, one or more layers of the active region 240 may be grown (e.g., on the first reflector 220) using a molecular beam epitaxy (MBE) process. Using an MBE process may achieve high-purity, epitaxial thin-film materials with a high degree of growth control (e.g., in terms of, for example, layer thickness). For example, the active region 240 may include MBE-grown InGaAsNSb quantum well layers and GaAsN quantum well barrier layers. In this case, the InGaAsNSb layers and the GaAsN layers may be lattice matched to a GaAs material used for substrate 210. Lattice matching of layers in the optical emitter 200 reduces a presence of defects in the optical emitter 200, which improves optical, electronic, and/or mechanical performance of the optical emitter 200.

In another example, active region 240 may be used for wavelengths of at least 1,100 nm (e.g., a lower end of an emission range of the optical emitter 200 being at least 1,100 nm). Additionally, or alternatively, active region 240 may be used for wavelengths of approximately 940 nm. In this way, by using GaAs-based dilute nitride, the optical emitter 200 can achieve a high PER, such as a PER of greater than 10 decibels (dB), greater than 15 dB, or greater than 20 dB, among other examples, across a range of currents, such as currents per emitter in a range of 3 milliamps (mA) to 300 mA, and across a range of temperatures, such as temperatures in a range of −20 degrees Celsius (° C.) to 105° C.

Oxidation aperture 250 may have a particular shape, which may affect a PER of a beam being emitted by the optical emitter 200. For example, the oxidation aperture 250 may be a circular oxidation aperture. Additionally, or alternatively, the oxidation aperture 250 may be a non-circular oxidation aperture, such as an elliptical oxidation aperture, as described in more detail below, or an irregular oxidation aperture. In some implementations, the oxidation aperture 250 may be a symmetric oxidation aperture (e.g., a circular or elliptical oxidation aperture) or an asymmetric oxidation aperture (e.g., an irregular oxidation aperture). Additionally, or alternatively, the oxidation aperture 250 may be associated with a configured size, which may affect a PER of a beam being emitted by the optical emitter 200. For example, the oxidation aperture 250 may have a diameter of less than 10 micrometers (μm), less than 6 μm, or less than 3 μm, among other examples. As used herein, “diameter” of the oxidation aperture 250 refers to a maximum diameter. In other words, a less than 10μm diameter elliptical oxidation aperture has a maximum diameter of less than 10 μm. In this way, by having a relatively small oxidation aperture, the optical emitter 200 can achieve a relatively high PER. Although limiting the oxidation aperture can reduce output power, an optical system may include an optical emitter array of many optical emitters 200 to achieve a particular output power or other output characteristic, rather than using a single optical emitter or fewer optical emitters with larger oxidation apertures. For example, in one configuration, an optical system may include a dilute-nitride VCSEL array of 36 optical emitters 200 with 5 μm oxidation apertures lasing at approximately 1380 nm. In this case, the 36 optical emitters 200 may use InGaAsNSb/GaAsN active regions on 2-degree off-cut GaAs substrates, as described below, to achieve a PER of greater than 15 dB across per emitter currents from 3 mA to 300 mA and temperatures from −20° C. to 105° C. In this case, although limiting the oxidation aperture size reduces power, using smaller optical emitters enables improved PER, better redundancy (e.g., if a single optical emitter fails, a smaller percentage of output power is lost), and/or improved manufacturability, among other examples.

In some implementations, the optical emitter 200 may be included in an optical emitter array of an optical system. For example, an optical emitter array (e.g., a dilute nitride VCSEL array) may include a plurality of optical emitters 200, such as 2 or more optical emitters 200, 4 or more optical emitters 200, 8 or more optical emitters 200, 16 or more optical emitters 200, 32 or more optical emitters 200, or 64 or more optical emitters 200, among other examples. In this case, the plurality of optical emitters 200 may include one or more first optical emitters 200 configured for a first wavelength and one or more second optical emitters 200 configured for a second wavelength. In this way, the optical emitter array is configured for emission of a polarized beam at a plurality of discrete wavelengths or at a single, continuous wavelength (e.g., that is wider than is achievable using a single optical emitter). Additionally, or alternatively, each optical emitter 200 of the plurality of optical emitters 200 may be configured for the same wavelength, thereby enabling achievement of a greater optical power than is achievable by a single optical emitter or outputting a beam with a particular characteristic (e.g., a beam formed by an array of dots for gesture recognition or 3D sensing). In some implementations, each optical emitter 200 may output a beam with the same polarization state. Additionally, or alternatively, some optical emitters 200 of an optical emitter array may output a beam with a first polarization state and some other optical emitters 200 of the optical emitter array may output a beam with a second, different polarization state.

In this way, by using MBE-grown InGaAsN or InGaAsN quantum wells with GaAsN quantum well barriers lattice matched to a 2 degree off-cut GaAs substrate 210 with an oxidation aperture 250 of less than 6 μm, the optical emitter 200 can output polarized light (e.g., without a polarizing optical element being disposed in front of the oxidation aperture 250) with a PER of great than, for example, 10 dB.

As indicated above, FIG. 2 is provided as an example. Other examples may differ from what is described with regard to FIG. 2.

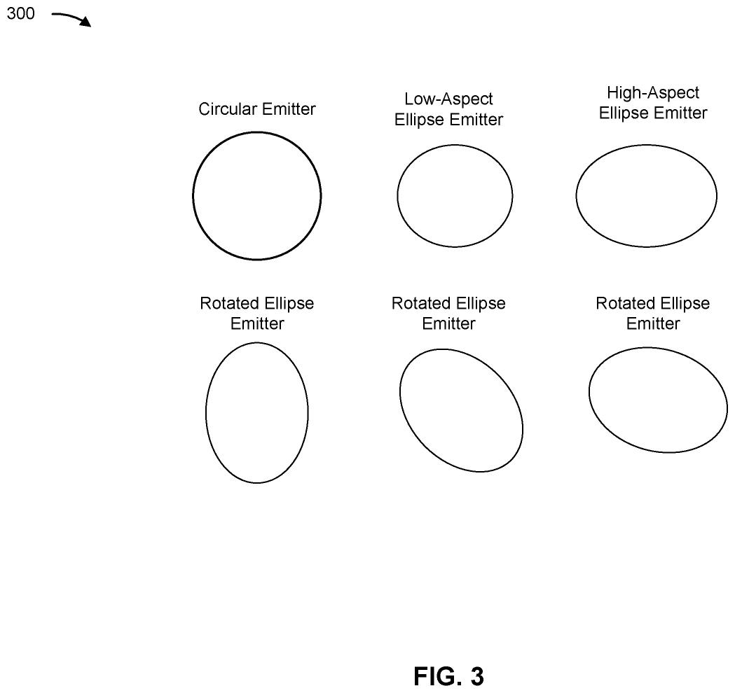

FIG. 3 is a diagram of an example 300 associated with an oxidation aperture for long-wavelength polarized emission.

As described above, an oxidation aperture 250 may have a particular shape, which may affect a PER of a beam being emitted by an optical emitter 200. Example 300 illustrates some types of oxidation aperture shapes that can be used for the optical emitter 200. For example, the optical emitter 200 may include a circular oxidation aperture or an elliptical oxidation aperture. Different types of elliptical oxidation apertures may include low-aspect elliptical oxidation apertures (e.g., more circular) and high-aspect elliptical oxidation apertures (e.g., less circular). Other types of oxidation aperture shapes for emitting polarized light may include oval oxidation apertures, ovate oxidation apertures, rectilinear oxidation apertures, or irregular oxidation apertures (e.g., non-symmetric oxidation apertures), among other examples. Additionally, or alternatively, an oxidation aperture 250 may be oriented in a particular manner. For example, as shown in example 300, an elliptical oxidation aperture can be rotated to different orientations relative to an optical emitter in which the elliptical oxidation aperture is present. The shape, size, and orientation of an oxidation aperture may be selected to achieve a particular PER in a particular orientation for a particular wavelength and under a particular set of conditions (e.g., current, power, or temperature conditions, among other examples).

As indicated above, FIG. 3 is provided as an example. Other examples may differ from what is described with regard to FIG. 3.

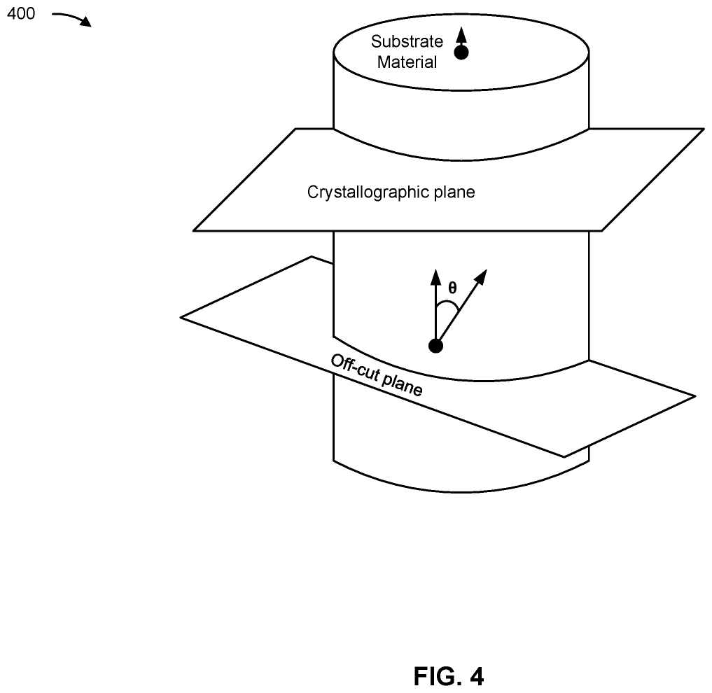

FIG. 4 is a diagram of an example 400 associated with an off-cut substrate for long-wavelength polarized emission.

The substrate 210, described above, may be manufactured by providing a wafer of a material with a crystalline structure. In one example, the wafer may be formed by cutting a substrate material along a crystallographic plane, as shown in example 400. Examples of planes that may be used may include approximately (100), (110), (211), (311), (111)A, and (111B) including the symmetric plans like (110) versus (1-10) versus (011) and any plane angles in-between the primary planes, among other examples. In another example, the wafer may be formed by cutting the substrate material in an off-cut at an angle θ from the crystallographic plane, as further shown in example 400. For example, the substrate 210 may include a 2 degree off-cut GaAs material, which may achieve a higher PER for an optical emitter than is achieved using a substrate formed by cutting the substrate material along the crystallographic plane.

As indicated above, FIG. 4 is provided as an example. Other examples may differ from what is described with regard to FIG. 4.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical emitter, comprising:
a substrate with a surface that is off-cut relative to an orientation of a crystallographic plane of the substrate;
a first set of layers disposed on the substrate and forming an active region of a light emitting junction,
wherein the first set of layers includes a gallium-arsenic-nitrogen (GaAsN) material layer,
wherein the GaAsN material layer forms a quantum well barrier,
wherein the first set of layers further includes an indium-gallium-arsenic-nitrogen-antimony (InGaAsNSb) layer,
wherein the InGaAsNSb layer is a strained, dilute nitride InGaAsNSb layer forming a quantum well; and
a second set of layers forming a first distributed Bragg reflector (DBR) and a second DBR,
wherein the active region is disposed between the first DBR and the second DBR.

2. The optical emitter of claim 1, wherein the second set of layers includes a GaAs material layer.

3. The optical emitter of claim 1, further comprising:
an asymmetric oxidation aperture.

4. The optical emitter of claim 1, wherein the substrate is a GaAs substrate.

5. The optical emitter of claim 1, wherein the first set of layers are grown by a molecular beam epitaxy (MBE) process.

6. The optical emitter of claim 1, wherein the optical emitter is configured to emit polarized light across a configured range of currents and a configured range of temperatures.

7. The optical emitter of claim 1, wherein the first set of layers is configured to achieve a polarization extinction ratio of greater than a threshold for a wavelength of at least 1200 nanometers (nm).

8. An optical system, comprising:
a gallium-arsenide (GaAs) substrate with a surface that is off-cut relative to an orientation of a crystallographic plane of the GaAs substrate;
an array of optical emitters disposed on the surface of the GaAs substrate,
each optical emitter, of the array of optical emitters, including:
a first distributed Bragg reflector (DBR) disposed on the GaAs substrate,
a second DBR, and
an active region disposed between the first DBR and the second DBR, the active region including a set of layers,
wherein the set of layers includes a gallium-arsenic-nitrogen (GaAsN) material layer and an indium-gallium-arsenic-nitrogen-antimony (InGaAsNSb) layer.

9. The optical system of claim 8, wherein the array of optical emitters includes two or more optical emitters.

10. The optical system of claim 8, wherein a plurality of optical emitters, of the array of optical emitters, are configured for emission at a same polarization.

11. The optical system of claim 8, wherein a first optical emitter, of the array of optical emitters, is configured for emission at a first polarization, and a second optical emitter, of the array of optical emitters, is configured for emission at a second polarization that is different from the first polarization.

12. The optical system of claim 8, wherein the array of optical emitters is a dilute nitride vertical cavity surface emitting laser (VCSEL) array.

13. The optical system of claim 8, wherein the set of layers is lattice matched to the GaAs substrate on which the set of layers is grown via molecular beam epitaxy.

14. The optical system of claim 8, wherein a lower end of an emission range of the array of optical emitters is at least 1100 nanometers.

15. An optical emitter, comprising:
a first set of layers forming an active region of a light emitting junction,
wherein the first set of layers includes a gallium-arsenic-nitrogen (GaAsN) material layer,
wherein the GaAsN material layer forms a quantum well barrier,
wherein the first set of layers further includes an indium-gallium-arsenic-nitrogen-antimony (InGaAsNSb) layer,
wherein the InGaAsNSb layer is a strained, dilute nitride InGaAsNSb layer forming a quantum well, and
a second set of layers forming a first distributed Bragg reflector (DBR) and a second DBR, the active region being disposed between the first DBR and the second DBR,
wherein the second set of layers includes a material with greater than a threshold refractive index; and
an oxidation aperture.

16. The optical emitter of claim 15, wherein the oxidation aperture is at least one of:
a circular oxidation aperture,
an elliptical oxidation aperture,
an oval oxidation aperture, or
an ovate oxidation aperture.

17. The optical emitter of claim 15, wherein the oxidation aperture is less than 10 micrometers in maximum diameter.

18. The optical emitter of claim 15, wherein the oxidation aperture is a symmetric oxidation aperture and the optical emitter is configured to output polarized light without a polarizing optical element being disposed in front of the oxidation aperture.

19. The optical emitter of claim 15, wherein the first set of layers is disposed on a gallium-arsenide (GaAs) substrate, wherein the GaAs substrate is off-cut relative to an orientation of a crystallographic plane of the GaAs substrate.

20. The optical emitter of claim 19, wherein the GaAs substrate is off-cut by greater than or equal to 2 degrees relative to the orientation of the crystallographic plane of the GaAs substrate.
